(19) United States
(12) Patent Application Publication
(10) Pub. No.: US 2015/0070680 A1
(43) Pub. Date: Mar. 12, 2015

(54) STAGE APPARATUS, LITHOGRAPHY APPARATUS, AND METHOD OF MANUFACTURING DEVICE

(71) Applicant: CANON KABUSHIKI KAISHA, Tokyo (JP)

(72) Inventor: Hitoshi Nakano, Utsunomiya-shi (JP)

(21) Appl. No.: 14/480,375

(22) Filed: Sep. 8, 2014

(30) Foreign Application Priority Data
Sep. 10, 2013 (JP) 2013-187307

(51) Int. Cl. G01B 11/14; G03F 7/20

(52) U.S. Cl. CPC G01B 11/14; G03F 7/70775; G03F 7/70725
USPC 355/72; 356/508

(57) ABSTRACT

A stage apparatus includes: a first blowing unit configured to blow out temperature-controlled gas to a measurement optical path of the first interferometer and a measurement optical path of a second interferometer; and a second blowing unit configured to blow out temperature-controlled gas to the measurement optical path of the second interferometer, wherein the first blowing unit blows out gas in a direction along an X-direction, and the second blowing unit blows out the gas obliquely with respect to a Y-direction from an upstream side to a downstream side of the gas blown out from the first blowing unit.

### BACKGROUND OF THE INVENTION

1. Field of the Invention

This disclosure relates to a stage apparatus including a moving member movable in an X-direction and a Y-direction, and an interferometer configured to measure the position of the moving member. This disclosure also relates to a lithography apparatus provided with the stage apparatus, or a method of manufacturing a device in which the lithography apparatus is used.

2. Description of the Related Art

In the related art, a lithography apparatus is used for manufacturing semiconductor devices or liquid crystal devices by using a photolithography technique. The lithography apparatus includes a stage apparatus configured to position an object (for example, a wafer) in an X-direction and a Y-direction, and the stage apparatus includes a moving member movable with the object mounted thereon, and an interferometer configured to measure the position of the moving member.

The interferometer readily causes a measurement error due to variation caused by environmental changes (for example, gas temperature changes) of a measurement optical path. Therefore, the stage apparatus is normally provided with a blowing unit configured to blow out temperature-controlled gas toward the measurement optical path. Japanese Patent Laid-Open No. 9-82626 discloses a stage apparatus provided with an X-direction interferometer and a Y-direction interferometer, wherein gas is blown out from a single blowing unit along an X-direction. Japanese Patent No. 3637639 discloses a configuration in which gas is blown out obliquely toward measurement optical paths for both of an X-direction interferometer and a Y-direction interferometer.

However, with the configuration disclosed in Japanese Patent Laid-Open No. 9-82626, a temperature distribution in the measurement optical path of the Y-direction interferometer varies due to a change of a gas flow caused by hitting against a structure (for example, an optical projection system) of the apparatus, or by being mixed up with gas heated by a heating member.

Japanese Patent No. 3637639 discloses a configuration in which the gas is blown out obliquely with respect to the two measurement optical paths from the single blowing unit, and hence the length of the width of an outlet becomes large. For example, in the case where the gas is blown out to the measurement optical path extending over an entire moving region of the moving member, provision of an outlet having a width not smaller than a length between opposing corners of the moving region is required. Therefore, a large space is occupied by arrangement of the blowing unit configured as described above, and a reduction in size of the apparatus becomes difficult.

### SUMMARY OF THE INVENTION

In view of such points described above, this disclosure provides a stage apparatus advantageous for a reduction in size of the apparatus by reducing variation of a temperature distribution in measurement optical paths of an X-direction interferometer and a Y-direction interferometer.

This disclosure provides a stage apparatus including: a moving member movable in a first direction and a second direction; a first interferometer configured to measure a position of the moving member in the first direction by using light radiated toward the moving member and traveling along the first direction; a second interferometer configured to measure a position of the moving member in the second direction by using light radiated toward the moving member and traveling along the second direction; a first blowing unit configured to blow out temperature-controlled gas to a measurement optical path of the first interferometer and a measurement optical path of a second interferometer; and a second blowing unit configured to blow out temperature-controlled gas to the measurement optical path of the second interferometer, wherein the first blowing unit blows out the gas in the direction along the first direction, and the second blowing unit blows out the gas obliquely with respect to the second direction from an upstream side to a downstream side of the gas blown out from the first blowing unit.

Further features of the present invention will become apparent from the following description of exemplary embodiments with reference to the attached drawings.

### BRIEF DESCRIPTION OF THE DRAWINGS

FIG. 1 is a top view illustrating a configuration of a semiconductor exposure apparatus.

FIG. 2 is a side view illustrating the configuration of the semiconductor exposure apparatus.

FIG. 3 is a drawing illustrating a gas flow from a blowing unit in a case where a moving member is moved to a position where a measurement optical path is the longest.

FIG. 4 is a drawing illustrating a gas flow from the blowing unit in a case where the moving member is moved to a position where the measurement optical path is the shortest.

### DESCRIPTION OF THE EMBODIMENTS

Referring now to the attached drawings, a preferred embodiment of this disclosure will be described below. In the respective drawings, the same members are denoted by the same reference numerals and overlapped description is omitted.

### Embodiment

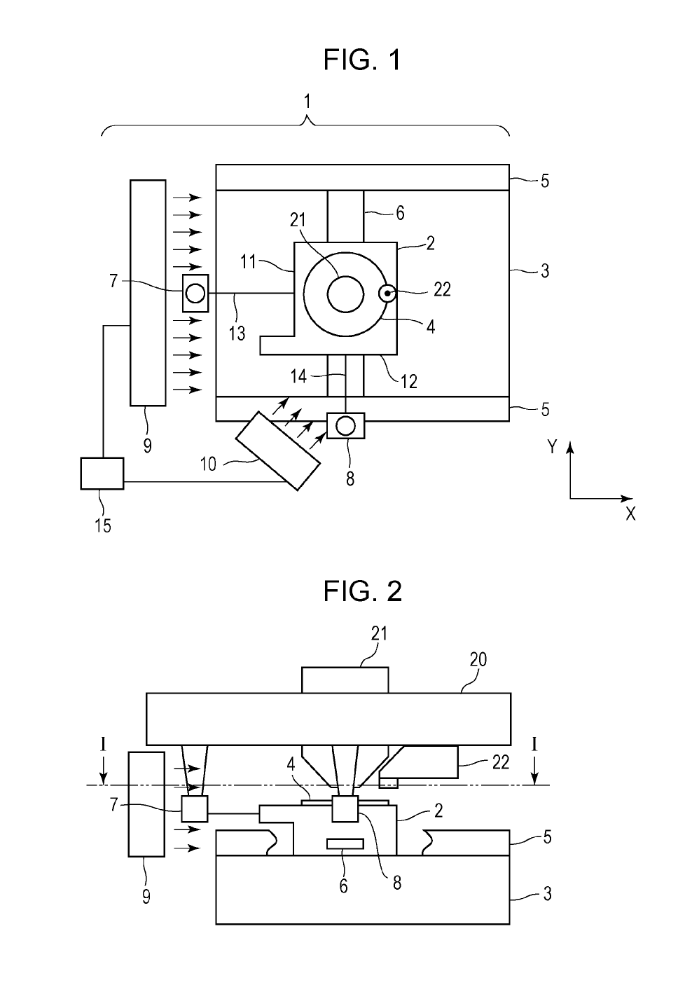

FIG. 1 and FIG. 2 are drawings schematically illustrating a semiconductor exposure apparatus to which a stage apparatus of an embodiment is applied. FIG. 1 is a top view of the semiconductor exposure apparatus illustrated in viewed in a direction indicated by an arrow I in FIG. 2.

The semiconductor exposure apparatus includes an optical projection system 21 (transfer unit) configured to project a pattern formed on a reticle by using light passing through the reticle, which is not illustrated, on a wafer 4 (substrate). The semiconductor exposure apparatus also includes a stage apparatus 1 configured to position the wafer (object) in an X-direction (first direction) and a Y-direction (second direction) orthogonal to each other in order to transfer the pattern to a desired position on the wafer 4.

The stage apparatus 1 includes a stage platen 3 (base member), a moving member 2 configured to allow a wafer to be placed thereon and being movable in the X-direction and the Y-direction along an upper surface of the stage platen 3, and an X linear motor 5 and a Y linear motor 6 configured to drive the moving member 2. The X linear motor 5 and the Y linear motor 6 are each provided with a guide, not illustrated. In this configuration, the Y linear motor 6 and the moving member 2 move integrally in the X-direction by being driven by the two X linear motors 5, and the moving member 2 moves in the Y-direction by being driven by the Y linear motor 6.

The stage apparatus 1 further includes an X-axis laser interferometer (hereinafter, referred to as X interferometer) 7 and a Y-axis laser interferometer (hereinafter, referred to as Y interferometer) 8 configured to measure the position of the moving member 2. Light from a light source, which is not illustrated, is guided by the X interferometer 7, and is separated into reference light traveling toward a fixed mirror (not illustrated) in the X interferometer 7 and measurement light traveling toward a reflecting surface 11 provided on the moving member 2 by a beam splitter in the X interferometer 7. The measurement light irradiated toward the moving member and traveling along the X-direction is reflected by the reflecting surface 11, and the measurement light reflected by the reflecting surface 11 interferes with the reference light guided in the beam splitter in the X interferometer 7 by a predetermined distance. The X interferometer 7 measures the position (displacement) of the moving member 2 in the X-direction by detecting the state of the interference light. The Y interferometer 8 also measures a position (displacement) of the moving member 2 in the Y-direction by using light reflected by a reflecting surface 12 provided on the moving member 2 in the same manner. In the drawing, measurement optical paths 13 and 14 of the respective interferometers are illustrated.

Results of measurement by the X interferometer 7 and the Y interferometer 8 are input to a control unit, which is not illustrated, via a signal line such as a cable. The control unit performs feedback control on the basis of target positional information of the moving member 2 and the input results of measurement, and outputs a current signal to be supplied to the X linear motor 5 and the Y linear motor 6. In this manner, by controlling the movement of the moving member 2 by the control unit, the moving member 2 is positioned at a desired position.

The optical projection system 21, the X interferometer 7, and the Y interferometer 8 are supported by a main body structure 20. The main body structure 20 is supported by an air mount (not illustrated) and a supporting pole (not illustrated) from a floor surface. An alignment scope 22 is further supported by the main body structure 20. The alignment scope 22 detects a mark formed on the wafer 4. A position of an existing pattern formed on the wafer 4 is detected by using the result of detection by the alignment scope 22 and outputs from the X interferometer 7 and the Y interferometer 8, so that a new pattern may be transferred onto the existing pattern in a superimposed manner.

The interferometer readily causes a measurement error due to variation caused by environmental changes of the measurement path (for example, changes in temperature and gas pressure). Therefore, in the embodiment, the stage apparatus 1 is provided with blowing units (blowing devices) 9 and 10 that blow temperature-controlled gas. The blowing units 9 and 10 include a dust-removing filer (for example, ULPA filter), and an outlet for blowing out gas via the dust-removing filter. A dust-preventing filter may be provided upstream of the outlet, or the dust-removing filter may be provided at the outlet.

The blowing unit 9 blows out gas toward an entire space on the stage platen 3 from behind the X interferometer 7. In other words, gas is blown out not only to the measurement optical path 13 of the X interferometer 7, but also to the measurement optical path 14 of the Y interferometer 8. Therefore, a width of the outlet of the blowing unit 9 in the longitudinal direction (Y-direction) is larger than a width of the moving member 2 in the Y-direction. Preferably, a width B_{y} of the outlet of the blowing unit 9 satisfies the following condition in a case where a width of a moving region of the moving member 2 in the Y-direction is defined as S_{y}.

0.7×S_{y}≦B_{y}

The blowing unit 9 blows out air to the upper surface of the stage platen 3 and a lower surface of the main body structure 20 substantially in parallel thereto.

The blowing unit 10 blows out temperature-controlled gas locally to the measurement optical path 14 of the Y interferometer 8. In the blowing unit 10, the width of the outlet of the blowing unit 10 in the longitudinal direction (oblique direction) is smaller than the width of the blowing unit 9 in the longitudinal direction. Preferably, a width B₂ of the outlet of the blowing unit 10 satisfies the following condition.

B₂≦(1/2)×B_{y}

The blowing unit 10 is configured to blow out gas obliquely with respect to the Y-direction in the direction from an upstream side to a downstream side (from the left to the right in FIG. 1) of the gas blown out from the blowing unit 9. The direction of the gas that the blowing unit 10 blows out preferably forms an angle between 20 to 70 degrees (counterclockwise) with respect to the Y-direction. In a case where the outlet port is divided as described later, or in a case where a plurality of the outlets are arranged in parallel, the B_{y} and B₂ described above indicate a total width thereof.

The blowing unit 9 forms a large gas flow flowing along the X-direction over the entire space on the stage platen 3. Accordingly, a temperature distribution in the entire space may be reduced and, in addition, a concentration of dust can be reduced. In the space on the stage platen 3, various structures such as the moving member 2, the optical projection system 21, and the alignment scope 22 are arranged. The gas from the blowing unit 9 hits against these structures while the temperature varies by heat exchange between the gas and the structure and flows into the measurement optical path of the Y interferometer 8. According to the embodiment, since the air-conditioned gas is blown out locally to the measurement optical path of the Y interferometer 8 by the blowing unit 10, variations of the temperature distribution in the measurement optical path of the Y interferometer 8 can be reduced. Here, since the blowing unit 10 blows out the gas obliquely from the upstream side to the downstream side of the gas blown from the blowing unit 9, the gas flow in the measurement optical path 13 of the X linear motor 7 or the influence on the temperature distribution may be reduced. For example, in the case where the blowing unit configured to blow out gas parallel to the Y-direction instead of the blowing unit 10 is provided, gas parallel to the X-direction from the blowing unit 9 and the gas parallel to the Y-direction hit against each other, and the turbulence of the gas flow or the temperature distribution is increased, which is not preferable.

The flow amount of gas blown out from the blowing units 9 and 10 is controlled by a gas control unit 15. The gas control unit 15 controls blowing of the gas by the blowing unit 9 and the blowing unit 10 so that the flow amount of gas that the blowing unit 9 blows out becomes larger than the flow amount of gas that the blowing unit 10 blows out. Preferably, the flow amount of gas blown out from the blowing unit 10 is not higher than 50% of the flow amount of gas blown out from the blowing unit 9. Accordingly, an influence on the gas flow or the temperature distribution in the measurement optical path 13 of the X interferometer 7 may further be reduced.

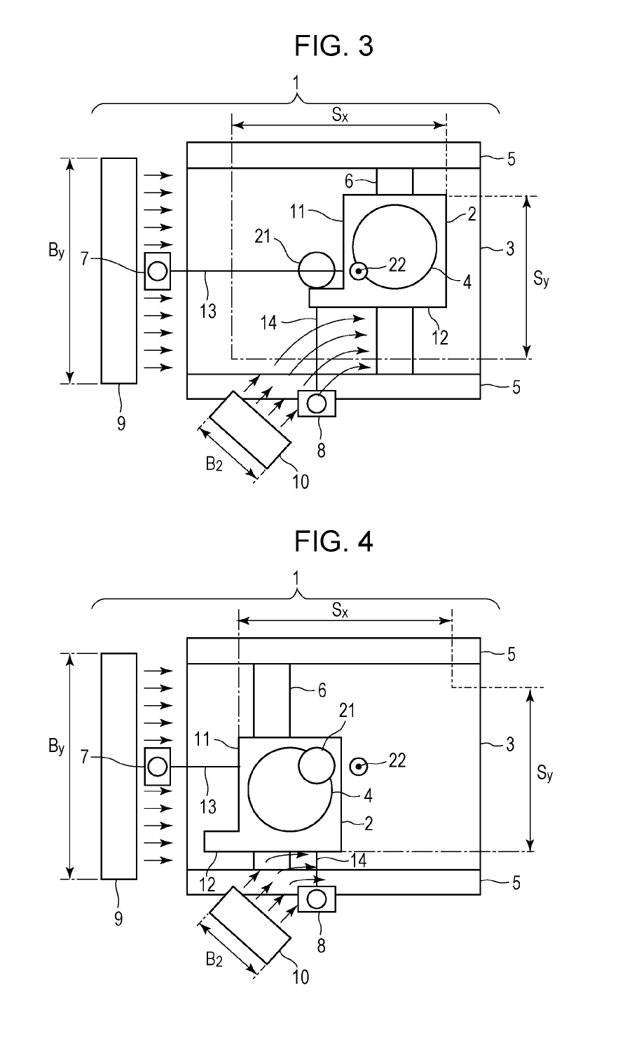

FIG. 3 and FIG. 4 are drawings illustrating a gas flow from the blowing units 9 and 10. FIG. 3 illustrates a state in which the moving member moves to a position where the measurement optical paths 13 and 14 become the longest, and FIG. 4 illustrates a state in which the moving member moves to a position where the measurement optical paths 13 and 14 become the shortest. Gas from the blowing unit 10 is blown out from the upstream side to the downstream side of the gas from the blowing unit 9 and flows from the upstream side to the downstream side of the gas from the blowing unit 9 by the gas flow from the blowing unit 9 or by hitting against the moving member 2.

In the embodiment, a width Sₓ of the moving region of the moving member 2 in the X-direction is larger than the width S_{y} in the Y-direction. The blowing unit 9 in the embodiment is capable of forming the gas flow in the entire space on the stage platen 3 having a width of the outlet smaller than that in the configuration in which gas is blown out along the X-direction (in comparison with the configuration in which gas is blown out along the Y-direction). In the embodiment, the direction in which the optical projection system 21 and the alignment scope 22 are arranged in parallel corresponds to the X-direction, and the gas is preferably blown out along the direction of parallel arrangement.

The blowing unit 10 may blow out the gas obliquely with respect to the X-direction, and may blow out the gas obliquely with respect to the upper surface of the stage platen 3. The blowing unit 10 may blow out gas perpendicularly upward, or perpendicularly downward as long as temperature-controlled gas flows over the major part of the measurement optical path 14. This direction may be determined according to the arrangement of a structure which causes heat turbulence. For example, in the case of the configuration of blowing the gas perpendicularly downward, the temperature variation of the gas due to heat generation from the linear motor 5 may be reduced.

The directions of the gases blown out from the blowing units 9 and 10 are determined by the angles of arrangement of the blowing units 9 and 10 or the angle of outlets (the orientations). When the blowing units 9 and 10 have a wind direction adjusting plate such as a louver, the direction of the gas depends on the angle of the adjusting plate.

The temperatures of the gases blown out from the blowing units 9 and 10 are preferably controlled independently. The blowing unit 9 may control the temperature of the gas by dividing the outlet into a plurality of segments, and the temperature of the gas at the respective segments independently. Accordingly, the temperature distribution may be reduced. The temperature of the gas may be controlled on the basis of the output of a temperature sensor by providing the temperature sensor.

In the embodiment, the semiconductor exposure apparatus has been exemplified. However, this disclosure is not limited thereto. For example, this disclosure can be applied to various types of lithography apparatus such as a liquid crystal exposure apparatus (a flat panel display manufacturing apparatus), an imprint apparatus, and a charged particle radiation drawing apparatus. As long as the apparatus which is provided with the stage apparatus configured to position the object by using the interferometer, this disclosure is not limited to the lithography apparatus. For example, this disclosure is also applicable to processing apparatus and inspection apparatus.

Subsequently, a method of manufacturing the device of the embodiment of this disclosure (a semiconductor device, a liquid crystal display device, etc.) will be described. The method of manufacturing the device includes a step of transferring (forming) a pattern on a substrate (wafer, glass plate, film-type substrate) by using the lithography apparatus described above. In addition, a step of etching the substrate to which the pattern is transferred (processing step) may be included. In the case of manufacturing other articles such as patterned media (recording media) or optical devices, the manufacturing method may include, instead of the etching step, other processing steps of processing the substrate on which the pattern is transferred.

Although the embodiment of this disclosure has been described, this disclosure is not limited to the embodiment, and various modifications or variations may be made within the scope of this disclosure.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-187307, filed Sep. 10, 2013 which is hereby incorporated by reference herein in its entirety.

What is claimed is:

1. A stage apparatus including: a moving member movable in a first direction and a second direction; a first interferometer configured to measure a position of the moving member in the first direction by using light radiated toward the moving member and traveling along the first direction; and a second interferometer configured to measure a position of the moving member in the second direction by using light radiated toward the moving member and traveling along the second direction, comprising:
a first blowing unit configured to blow out temperature-controlled gas to a measurement optical path of the first interferometer and a measurement optical path of a second interferometer; and a second blowing unit configured to blow out temperature-controlled gas to the measurement optical path of the second interferometer, wherein
the first blowing unit blows out the gas in the direction along the first direction, and the second blowing unit blows out the gas obliquely with respect to the second direction from an upstream side to a downstream side of the gas blown out from the first blowing unit.

2. The stage apparatus according to claim 1, further comprising a control unit configured to control blowing of the gas by the first blowing unit and the second blowing unit so that a flow amount of gas that the first blowing unit blows out becomes larger than a flow amount of gas that the second blowing unit blows out.

3. The stage apparatus according to claim 1, wherein
a width of a moving region in the second direction of the moving member is smaller than a width of a moving region in the first direction of the moving member.

4. The stage apparatus according to claim 1, wherein
where B_{y} is a width of an outlet of the first blowing unit in the second direction and S_{y} is a width of the moving region in the second direction of the moving member, the relationship
0.7×S_{y}≦B_{y}
is satisfied.

5. The stage apparatus according to claim 4, wherein
where B₂ is a width of an outlet of the second blowing unit in a longitudinal direction, the relationship
B₂≦(1/2)×B_{y}
is satisfied.

6. The stage apparatus according to claim 1, wherein
an angle formed between the second blowing unit and the second direction is 20 to 70 degrees.

7. The stage apparatus according to claim 1, further wherein
the moving member includes a base member moving in the first direction and the second direction along an upper surface thereof, and
the first blowing unit blows out the gas in a direction along the upper surface of the base member.

8. The stage apparatus according to claim 7, wherein
the second blowing unit blows out the gas in a direction obliquely with respect to the upper surface of the base member.

9. The stage apparatus according to claim 1, wherein
the first direction and the second direction are orthogonal to each other.

10. A lithography apparatus comprising:
a transfer unit configured to transfer a pattern to a substrate;
a moving member allowing the substrate to be mounted thereon and movable in a first direction and a second direction;
a first interferometer configured to measure a position of the moving member in the first direction by using light radiated toward the moving member and traveling along the first direction;
a second interferometer configured to measure a position of the moving member in the second direction by using light radiated toward the moving member and traveling along the second direction;
a first blowing unit configured to blow out temperature-controlled gas to a measurement optical path of the first interferometer and a measurement optical path of a second interferometer; and
a second blowing unit configured to blow out temperature-controlled gas to the measurement optical path of the second interferometer, wherein
the moving member is arranged at a position allowing a positional measurement by the first and second interferometers so as to face the transfer unit, and
the first blowing unit blows out the gas in a direction along the first direction, and the second blowing unit blows out the gas obliquely with respect to the second direction from an upstream side to a downstream side of the gas blown out from the first blowing unit.

11. The lithography apparatus according to claim 10 comprising:
an alignment scope configured to detect a mark formed on the substrate, wherein
the transfer unit and the alignment scope are arranged in parallel along the first direction.

12. A method of manufacturing a device comprising:
forming a pattern on a substrate by using a lithography apparatus; and
processing the substrate on which the pattern is formed in the previous step, wherein
the lithography apparatus includes:
a transfer unit configured to transfer a pattern to a substrate;
a moving member allowing the substrate to be mounted thereon and movable in a first direction and a second direction;
a first interferometer configured to measure a position of the moving member in the first direction by using light radiated toward the moving member and traveling along the first direction;
a second interferometer configured to measure a position of the moving member in the second direction by using light radiated toward the moving member and traveling along the second direction;
a first blowing unit configured to blow out temperature-controlled gas to a measurement optical path of the first interferometer and a measurement optical path of a second interferometer; and
a second blowing unit configured to blow out temperature-controlled gas to the measurement optical path of the second interferometer, and wherein
the moving member is arranged at a position allowing a positional measurement by the first and second interferometers so as to face the transfer unit, and
the first blowing unit blows out the gas in a direction along the first direction, and the second blowing unit blows out the gas obliquely with respect to the second direction from an upstream side to a downstream side of the gas blown out from the first blowing unit.
